(19) United States
(12) Patent Application Publication
(10) Pub. No.: US 2009/0002951 A1
(43) Pub. Date: Jan. 1, 2009

(54) SYSTEM HAVING A HEAT TRANSFER APPARATUS

(75) Inventors: Anton Legen, Muenchen (DE); Steve Wood, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/771,575

(22) Filed: Jun. 29, 2007

(51) Int. Cl. H05K 7/20; F28D 15/00

(52) U.S. Cl. 361/715; 361/719; 165/104.33

(57) ABSTRACT

A system including a heat transfer apparatus is disclosed. One embodiment provides for an electronic device and a heat transfer apparatus including a heat distribution plate with a first surface being at least in part in thermal communication with the electronic device. The thermal conductivity of the heat distribution plate is higher in a direction substantially parallel to the first surface than in a direction perpendicular to the first surface.

### BACKGROUND

The present invention relates to a system having a heat transfer apparatus, an electronic device and a memory module.

Semiconductor devices continue to shrink and the frequencies at which the devices are operated are constantly increasing. The combination of reduced size and higher frequencies results in a higher power density that increases the temperature of the device. To prevent overheating of the device which may for example lead to malfunction, reduced functionality or even destruction of the device cooling solutions are used.

Cooling solutions are employed in most technical fields like for example consumer electronics (e.g., TV sets or HIFI components), computer (e.g., for processors, memories, chipsets or hard disks) or industrial electronics (e.g., power amplifier).

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a perspective view of a an electronic device equipped with a heat transfer apparatus according to an embodiment of the invention.

FIG. 2 illustrates a front view of the electronic device of FIG. 1.

FIG. 3 illustrates a perspective view of an electronic device equipped with a heat transfer apparatus according to an embodiment of the invention.

FIG. 4 illustrates a front view of the electronic device of FIG. 2.

FIG. 5 illustrates a front view of an electronic device equipped with a heat transfer apparatus according to an embodiment of the invention.

FIG. 6 illustrates a perspective view of an electronic device equipped with a heat transfer apparatus according to an embodiment of the invention.

FIG. 7 illustrates a diagram showing the temperature distribution along a direction of the electronic device.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

The following figures refer to embodiments of a system, electronic device and integrated circuit having a heat transfer apparatus. In one embodiment, the electronic device may be as exemplary illustrated a memory module, such as a DIMM (Dual Inline Memory Module), registered DIMM or FB-DIMM (Fully Buffered DIMM). The figures further refer to embodiments of a system, electronic device, integrated circuit and a memory module equipped with a heat transfer apparatus. For clarity, a memory and heat transfer apparatus are only shown in detail.

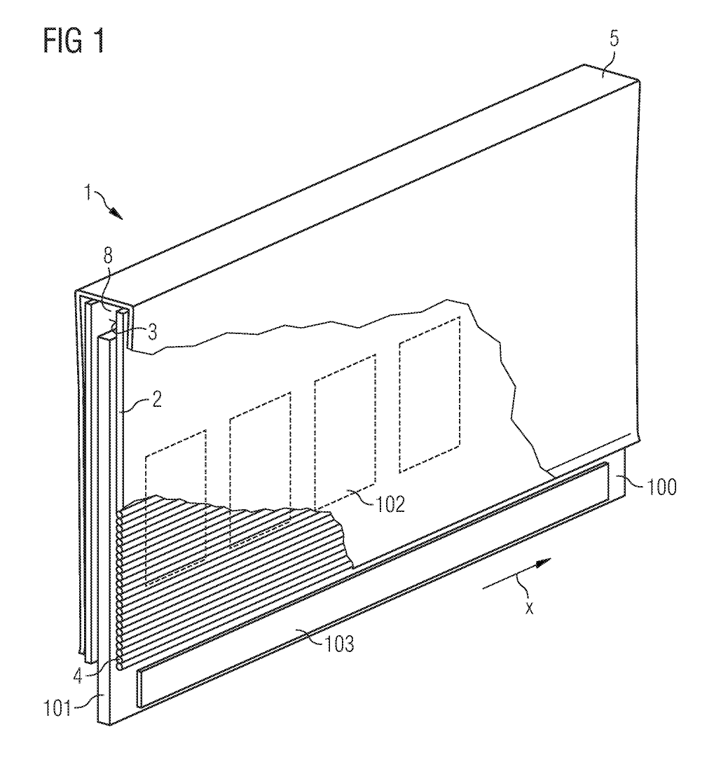

FIG. 1 is a perspective view of an embodiment of a system including a heat transfer apparatus 1 and an embodiment of a memory module 100. The heat transfer apparatus 1 is attached to the memory module 100. The memory module 100 includes a circuit board 101 on which components in the form of memory chips 102 are arranged. The circuit board 101 has an oblong shape wherein the longer side proceeds in a direction as indicated by the arrow x. Along a lower edge of the circuit board 101 contacts 103 are arranged in the direction x. The contacts 103 serve to connect the memory module 100 to a motherboard of a computer.

The arrangement of the memory chips 102 is an example. In this example the memory chips 102 are arranged in a single row along the direction x. The memory chips 102 can be provided on a single surface or on both surfaces of the circuit board 101. The amount of memory chips 102 can vary depending on the organization of the memory module 100 for example. The memory chips 102 might be arranged in two or more rows. Stacked chips can also be used. For FB-DIMM modules one or more AMB (Advanced Memory Buffer) chips can be attached to the circuit board 101.

The heat transfer apparatus 1 includes at least one heat distribution plate 2 including a first surface 3 which is in thermal communication with the memory module 100. The heat distribution plate 2 covers almost the complete surface of the circuit board 101 which carries the memory chips 102. The heat distribution plate 2 is in thermal contact at least with a part of the memory module 100, for example with the memory chips 102. Thermal communication does not require direct mechanical contact. It is sufficient if the heat sources, e.g., the memory chips 102 are connected via one or more thermal conductive media to the heat distribution plate 2.

In one embodiment illustrated the heat distribution plate 2 includes a plurality of heat pipes 4. A heat pipe may include a closed tube containing a fluid which evaporates at a point of high temperature thereby absorbing heat and which condenses at a point of lower temperature thereby emitting heat. Correspondingly a heat pipe can transport heat in the direction of the pipe.

The tube of a heat pipe can include metal like for example aluminum. The tubes of the plurality of heat pipes 4 may be attached to one another to form the heat distribution plate 2. The plurality of heat pipes 4 may be sandwiched between two plates wherein the plates may include metal like for example aluminum and wherein a filling material may be used to fill gaps between the plurality of heat pipes 4. In another embodiment a compound material may be used to connect the plurality of heat pipes 4 wherein the two main surfaces of the heat distribution plate 2 could be polished.

The plurality of heat pipes 4 is arranged substantially in parallel to the direction x. Thus, the plurality of heat pipes 4 extends substantially in parallel to the first surface 3 of the heat distribution plate 2. In this embodiment the heat distribution plate 2 is completely filled with heat pipes 4. It is possible as well that only parts of the heat distribution plate 2 include heat pipes 4. Heat pipes 4 may be arranged only in areas of the heat distribution plate 2 which are in contact with memory chips 102 for example.

At least part of the plurality of heat pipes 4 spans the memory chips 102 so that the temperature of the memory chips 102 is balanced.

In another embodiment the heat distribution plate 2 includes graphite material. Graphite has a higher thermal conductivity in one direction than in another. In this embodiment the thermal conductivity is higher in the plane of the first surface 3 than perpendicular to it. In other words, the thermal conductivity is higher parallel to the first surface than in a direction perpendicular to the first surface.

The thermal conductivity is higher in a direction substantially parallel to the first surface 3 or substantially parallel to the direction x along which the plurality of heat sources is arranged. The temperature gradient over the electronic device is thereby minimized. This minimized temperature gradient provides for more efficient transfer of thermal energy from the electronic device to the fluid medium surrounding the heat transfer apparatus 1. This will be described in more detail for an embodiment of a memory module 100 in conjunction with FIG. 7.

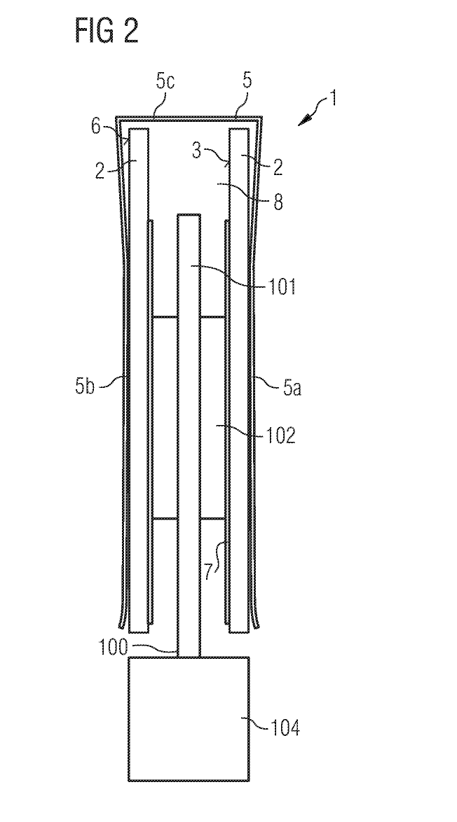

The structure of one embodiment of the heat transfer apparatus 1 as illustrated in FIG. 1 and FIG. 2 is explained in the following. The heat transfer apparatus 1 is attached to the memory module 100. The memory module 100 includes a circuit board 101 on both sides of which memory chips 102 are arranged. The memory module 100 is inserted into a socket 104 which could be part of a computer's motherboard.

The heat transfer apparatus 1 includes two heat distribution plates 2 which are in thermal communication with the memory chips 102. The heat distribution plates 2 are attached to the memory module 100 with a single clip 5. The heat distribution plate 2 contains a plurality of heat pipes 4 as described before. The heat distribution plate 2 has a length (in x direction) which is approximately the same as the length of the circuit board 101. The height of the heat distribution plate 2 is such that the contacts 103 are free for insertion into the socket 104 and that the heat distribution plate 2 exceeds the circuit board 101 at the top.

The clip 5 has a length (in x direction) which is approximately the same as the one of the heat distribution plate 2. The height of the clip 5 is approximately the same as the one of the heat distribution plate 2. The clip 5 has a first 5a and second 5b side member which are coupled by a connecting member 5c. The side members 5a and 5b engage the heat distribution plate 2 at second surfaces 6 which are opposite to the first surfaces 3. The clip 5 may be a resilient spring clip and may include metal. The connecting member 5c or the base of the clip 5 may be wider than the width of the memory module 100 to adapt the heat transfer apparatus 1 to a variety of memory modules. The side members 5a and 5b may be shaped to increase the contact area between the side members 5a and 5b and the second surfaces 6 of the heat distribution plate 2. The main contact area between the clip 5 and the heat distribution plates 2 is approximately in the middle of the height of the heat distribution plate 2.

Thermal conduction aids 7 may be provided between the memory chips 102 and the heat distribution plates 2. Thermal conduction aids include thermal conductive paste, soft metallic foil or the like.

The clip 5 attaches the heat distribution plates 2 to the memory module 100. The clip 5 may include spring force which is pressing the heat distribution plates 2 against the memory chips 102. Notches or recesses and lugs or noses can be used with the heat distribution plate 2, the clip 5 or the circuit board 101 to secure the heat transfer apparatus 1. The clip 5 is also suitable for other modules and other heat spreader designs.

In the upper part of the heat transfer apparatus 1a duct 8 may be provided for guiding the fluid medium surrounding the heat transfer apparatus 1 and the memory module 100. The top of the duct 8 is confined by the base or the connecting member 5c of the clip 5. In this embodiment the sides of the duct 8 are limited by the first surfaces 3 of the heat distribution plates 2. In another embodiment the sides of the duct 8 are defined by the side members 5a and 5b of the clip 5. A combination of both is possible as well. Upper sides of the duct 8 may be defined by the side members 5a and 5b of the clip 5 while lower sides of the duct 8 may be defined by the first surfaces 3 of the heat distribution plates 2 for example. The lower side of the duct 8 may be confined by the memory module 100, i.e. by the circuit board 101 and the memory chips 102.

The duct 8 supports the transportation of heat away from the memory module 100. The surrounding fluid medium like air is guided through the duct 8 in the direction x thereby absorbing heat from the heat distribution plates 2. Further, heat is transferred by the heat distribution plates 2 via the clip 5 to the surrounding fluid medium.

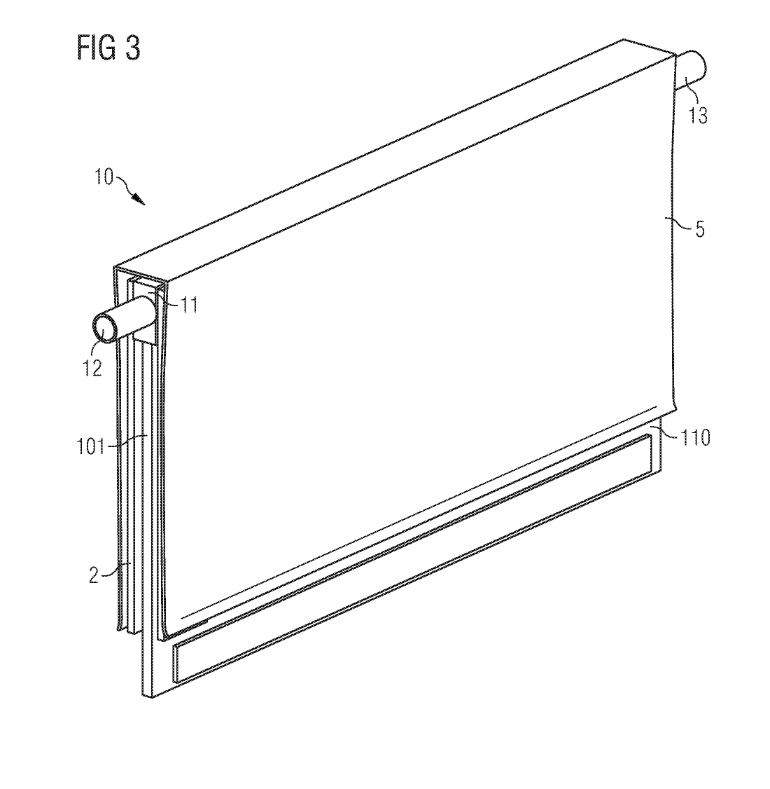

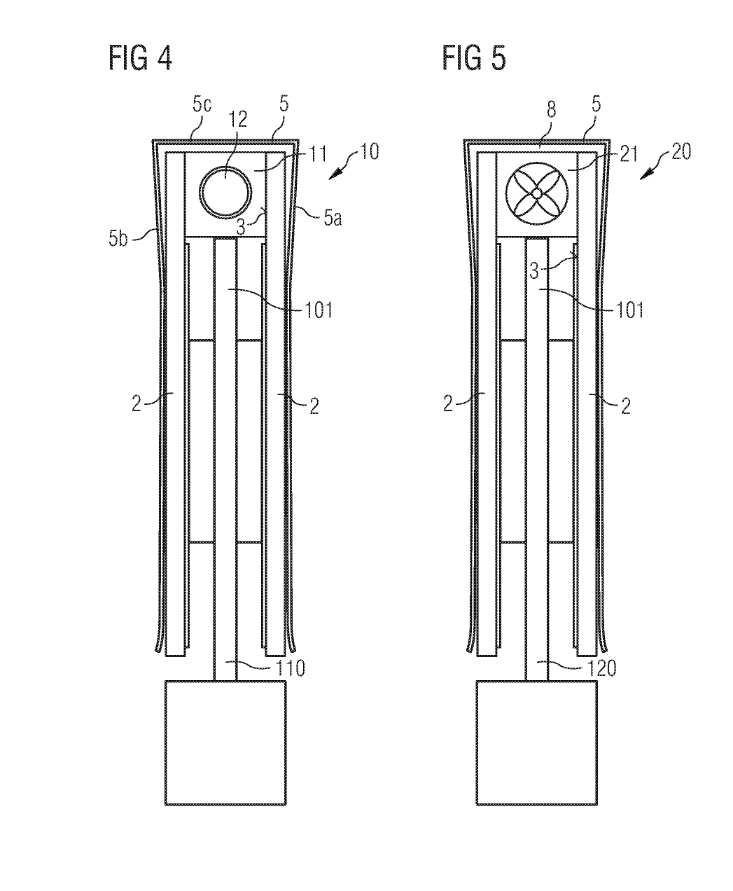

FIG. 3 and FIG. 4 illustrate a further embodiment of a heat transfer apparatus 10 and an embodiment of a memory module 110. The heat transfer apparatus 10 includes heat distribution plates 2 attached by the clip 5 to the memory module 110. In the upper part of the heat transfer apparatus 10 a cooling element 111 is provided. The cooling element 11 extends over the whole length of the heat transfer apparatus 10 and is in contact with the first surfaces 3 of the heat distribution plates 2. The cooling element 11 may further contact the top of the circuit board 101 and the connecting member 5a of the clip 5. The cooling element 11 could be arranged in the upper part of the clip 5 as well. The cooling element 11 is then attached to the connecting member 5a and to these parts of the side members 5a and 5b which are projecting above the heat distribution plates 2.

The cooling element 11 has an inlet 12 at a first end of the memory module 110 and an outlet 13 at a second end of the memory module 110. A cooling fluid is provided to the inlet 12 via a hose or tube for example, flows through the cooling element 11 to the outlet 13 where the fluid is leaving the cooling element 11. The cooling fluid could be water or any fluid medium capable of transporting heat. In a computer system having more than memory module the cooling element 11 of the memory modules 110 can be connected in series. Then, the outlet 13 of a first memory module is connected to an inlet 12 of a second memory module.

FIG. 5 illustrates an embodiment of a heat transfer apparatus 20 and an embodiment of a memory module 120. The heat transfer apparatus 20 includes heat distribution plates 2 attached by the clip 5 to the memory module 120. In the upper part of the heat transfer apparatus 20 a fan 21 is provided. The fan 21 is arranged in the duct 8 to enhance airflow through the duct 8. The fan 21 can be implemented at either end of the duct 8 or somewhere in between as well. Depending on the location of the fan 21 and the application the fan 21 may rotate to blow the fluid medium surrounding the memory module 120 into the duct 8 or may rotate to draw the fluid medium through the duct 8.

The fan 21 is in contact with the first surfaces 3 of the heat distribution plates 2. The fan 21 may further contact the top of the circuit board 101 and the connecting member 5a of the clip 5. The fan 21 could be arranged in the upper part of the clip 5 as well. The fan 21 is then attached to the connecting member 5a and to these parts of the side members 5a and 5b which are projecting above the heat distribution plates 2. The fan 21 can extend across the whole profile of the duct 8 or can cover the duct 8 only partially so that some flow can bypass the fan 21.

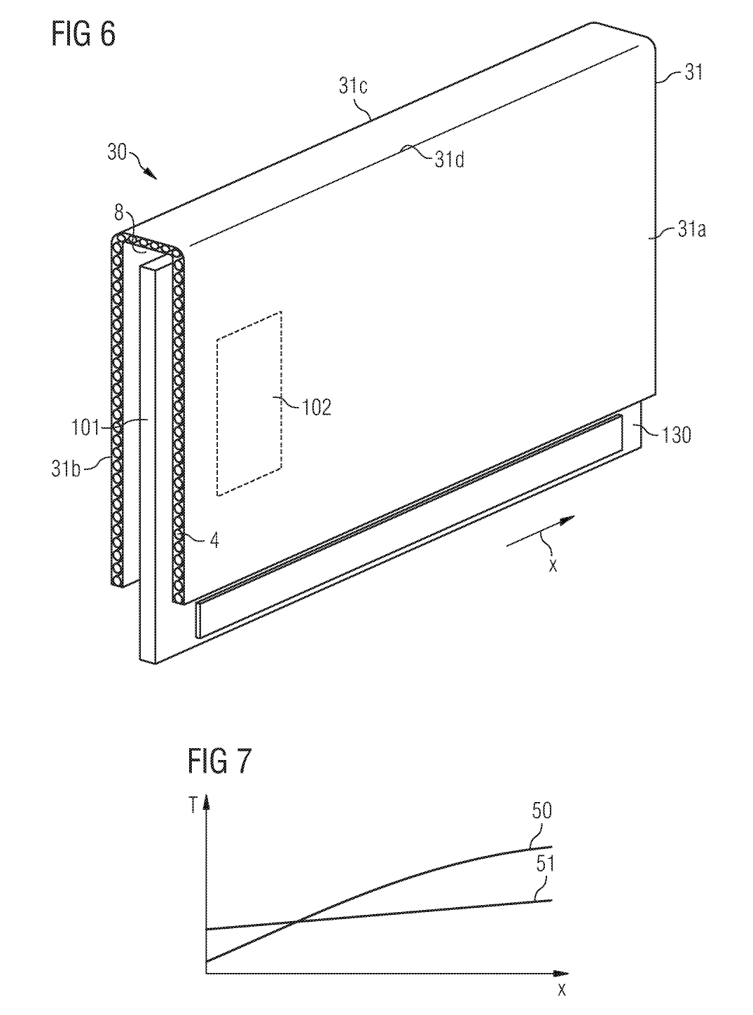

FIG. 6 illustrates an embodiment of a heat transfer apparatus 30 and an embodiment of a memory module 130. The memory module 130 includes a circuit board 101 on which memory chips 102 are arranged. The heat transfer apparatus 30 is attached to the memory module 130 and includes a heat distribution plate 31. The heat distribution plate 31 includes a plurality of heat pipes 4 which are arranged substantially parallel to a longitudinal side of the memory module 130 (direction x).

The heat distribution plate 31 has a first side member 31a covering a first side of the memory module 130 and being in thermal communication with the memory chips 102 mounted to this side. The heat distribution plate 31 further has second side member 31b covering a second side of the memory module 130 and being in thermal communication with the memory chips 102 mounted to this side. The side members 31a and 31b are coupled by a connecting member 31c which is accommodated above the memory module 130. The side members 31a and 31b are coupled to the connecting member 31c along coupling edges 31d which are parallel to the longitudinal side of the memory module 130 (direction x).

The height of the side members 31a and 31b and the orientation of the heat transfer apparatus 30 at the memory module 130 are chosen in such a way that a duct 8 is formed by the connecting member 31c and these parts of the side members 31a and 31b which are projecting above the circuit board 101. The duct 8 aids the flow of the fluid medium surrounding the memory module 130 thereby enhancing the transportation of heat away from the memory module 130.

The heat distribution plate 31 includes a resilient or springy material to attach the heat distribution plate 31 to the memory module 130. The heat distribution plate 31 may be biased to produce a spring force pressing the heat distribution plate 31 against the memory module 130.

Either the whole heat distribution plate 31 is comprised of a springy or resilient material or parts of the heat distribution plate 31 provide this functionality to attach the heat transfer apparatus 30 to the memory module 130.

For the production of the heat transfer apparatus 30 sheet material containing the plurality of heat pipes 4 is cut to size and these heat pipes which are in area of the coupling edges 31d are emptied. Alternatively these heat pipes will not be filled during the production of the sheet material. The tailored piece is bent along the coupling edges 31d to obtain the U-shape of the heat distribution plate 31.

FIG. 7 is a diagram illustrating the temperature distribution over a memory module in the longitudinal direction (x direction in the previous Figs.). This example describes an air cooled system in which air flows in the direction x. The airflow may be generated by one or more fans which can be placed in a housing of a computer or server.

Curve 50 illustrates the distribution for a memory module equipped with a conventional head spreader. It illustrates that the temperature is increasing over the length of the memory module. The first memory chip in x direction has the lowest temperature while the last chip in x direction has the highest temperature.

Curve 51 illustrates the heat distribution for a memory module equipped with a heat transfer apparatus according to an embodiment of the invention. It is apparent that the slope of curve 51 is smaller than of curve 50. Accordingly, the temperature gradient over the memory module in the direction x is smaller. The memory chips are having approximately the same temperature.

The area under the curves 50 and 51 can be interpreted as the amount of heat which has to be carried away from the memory module. It can be seen that the area underneath curve 51 is smaller than under curve 50.

The heat transfer apparatus 1 can be utilized in a test environment like for example illustrated in FIG. 2. A memory module 100 to be tested is inserted in a slot 104 of a test system (not illustrated). As the heat transfer apparatus 1 reduces the temperature gradient of the memory module 100 the memory chips 102 have approximately the same temperature, i.e. an almost identical condition for testing.

All kinds of electronic devices can be tested using the heat transfer apparatus like for example amplifiers, transistors or processors. The heat transfer apparatus reduces the temperature gradient of different parts of a device or the gradient between different devices thereby allowing for comparable conditions.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A system comprising:
an electronic device; and
a heat transfer apparatus comprising a heat distribution plate having a first surface being at least in part in thermal communication with the electronic device, wherein the thermal conductivity of the heat distribution plate is higher in a direction substantially parallel to the first surface than in a direction perpendicular to the first surface.

2. The system of claim 1, comprising wherein the electronic device comprises a plurality of heat sources mainly arranged along one direction and wherein the thermal conductivity of the heat distribution plate is higher in the one direction than in other directions.

3. The system of claim 2, comprising wherein the heat distribution plate comprises a plurality of heat pipes which proceed in the one direction.

4. The system of claim 1, comprising wherein the heat distribution plate comprises graphite.

5. The system of claim 1, comprising at least two heat distribution plates.

6. The system of claim 1, wherein the electronic device comprises a memory module.

7. The system of claim 1, wherein the electronic device comprises an integrated circuit.

8. The system of claim 7, comprising where the integrated circuit includes a printed circuit board and a memory.

9. A heat transfer apparatus for an electronic device comprising:
a heat distribution plate having a first surface being at least in part in thermal communication with the electronic device, wherein the thermal conductivity of the heat distribution plate is higher in a direction substantially parallel to the first surface than in a direction perpendicular to the first surface.

10. The apparatus of claim 9, comprising wherein the electronic device comprises a plurality of heat sources mainly arranged along one direction and wherein the thermal conductivity of the heat distribution plate is higher in the one direction than in other directions.

11. The apparatus of claim 10, comprising wherein the heat distribution plate comprises a plurality of heat pipes which proceed in the one direction.

12. The apparatus of claim 9, comprising wherein the heat distribution plate comprises graphite.

13. The apparatus of claim 9, comprising at least two heat distribution plates.

14. The apparatus of claim 9, wherein the electronic device is a memory module.

15. A heat transfer apparatus for a memory module comprising:
at least one heat distribution plate having a first surface being at least in part in thermal communication with the memory module, wherein the thermal conductivity of the heat distribution plate is higher in a direction substantially parallel to the first surface than in a direction perpendicular to the first surface.

16. The apparatus of claim 15, comprising two heat distribution plates arranged at opposite sides of the memory module, wherein a single clip attaches the two heat distribution plates to the memory module.

17. The apparatus of claim 16, comprising wherein the clip is a resilient spring clip.

18. The apparatus of claim 16, wherein the clip comprises metal.

19. The apparatus of claim 16, wherein the clip comprises a first and second side member and a connecting member coupling the first and the second side member, wherein the side members engage the heat distribution plates at second surfaces opposite to the first surfaces and substantially cover the second surfaces.

20. The apparatus of claim 19, comprising wherein a duct is formed by the connecting member and parts of the side members.

21. The apparatus of claim 15, wherein the heat distribution plate comprises a first and second side member and a connecting member coupling the first and the second side member along coupling edges, wherein the side members each comprise the first surface.

22. The apparatus of claim 21, wherein the heat distribution plate comprises a plurality of heat pipes which are orientated parallel to the coupling edges.

23. The apparatus of claim 21, wherein the heat distribution plate comprises springy material to attach the heat distribution plate to the memory module.

24. The apparatus of claim 21, wherein the side members are of greater height than the memory module so that a duct is formed between the connecting member, an upper side of the memory module and the portions of the side members projecting above the side of the memory module.

25. A memory module comprising:
a circuit board;
components mounted on the circuit board; and
a heat transfer apparatus comprising at least one heat distribution plate having a first surface being in thermal communication with the components, wherein the thermal conductivity of the heat distribution plate is higher in a direction substantially parallel to the first surface than in a direction perpendicular to the first surface.

26. The memory module of claim 25, comprising two heat distribution plates arranged at opposite sides of the circuit board, wherein one clip attaches the two heat distribution plates to the circuit board.

27. The memory module of claim 26, wherein the clip comprises a first and second side member and a connecting member coupling the first and the second side member, wherein the side members engage the heat distribution plates at second surfaces opposite to the first surfaces and substantially cover the second surfaces.

28. The memory module of claim 27, comprising wherein a duct is formed by the connecting member and parts of the side members.

29. The memory module of claim 28, comprising wherein a fan is provided in the duct to enhance airflow through the duct.

30. The memory module of claim 28, comprising wherein a cooling element is provided in the duct.

31. A heat transfer apparatus for an electronic device comprising:
a heat distribution means having a first surface means being at least in part in thermal communication with the electronic device, wherein the thermal conductivity of the heat distribution means is higher in a direction substantially parallel to the first surface means than in a direction perpendicular to the first surface means.

32. A method for cooling an electronic device, wherein the electronic device comprises a plurality of heat sources mainly arranged along one direction, comprising:
distributing heat along the one direction to approximate the temperature of the plurality of heat sources.

33. A test system for an electronic device comprising:
a contact device to contact the electronic device; and
a heat distribution plate having a first surface being at least in part in thermal communication with the electronic device, wherein the thermal conductivity of the heat distribution plate is higher in a direction substantially parallel to the first surface than in a direction perpendicular to the first surface.

34. A method for testing an electronic device, wherein the electronic device comprises a plurality of heat sources mainly arranged along one direction, comprising:
contacting the electronic device; and
distributing heat along the one direction to approximate the temperature.
